(19) United States
(12) Patent Application Publication
(10) Pub. No.: US 2025/0087933 A1
(43) Pub. Date: Mar. 13, 2025

(54) WIRING STRUCTURE OF ELECTRICAL APPLIANCE

(71) Applicant: Mitsubishi Electric Corporation, Tokyo (JP)

(72) Inventors: Yuki HIROSE, Tokyo (JP); Akifumi SHIMONO, Tokyo (JP); Taigi OKAZAKI, Tokyo (JP)

(73) Assignee: Mitsubishi Electric Corporation, Tokyo (JP)

(21) Appl. No.: 18/725,489

(22) PCT Filed: Oct. 4, 2022
(86) PCT No.: PCT/JP2022/037051

§ 371 Date: Jun. 28, 2024

(30) Foreign Application Priority Data
May 26, 2022 (JP) 2022-085766

(51) Int. Cl. H01R 13/52; H01R 13/66

(52) U.S. Cl. CPC H01R 13/5202; H01R 13/665

(57) ABSTRACT

The present application is to provide a wiring structure of an electrical appliance which can stabilize the amount of protrusion of a busbar from a control board.

The wiring structure of the electrical appliance includes: a connector fixed to a housing and has an outer connector housing and an inner connector housing; a busbar in which one side is arranged in the outer connector housing of the connector and the other side is extended to the outside of the inner connector housing of the connector; and a control board through which the other side of the busbar passes. Then, the wiring structure of the electrical appliance includes a gasket which is attached by insertion between an outer peripheral portion of the connector and an inner peripheral portion of the housing which faces the outer peripheral portion of the connector, and seals a gap between the connector and the housing.

### TECHNICAL FIELD

The present application relates to a wiring structure of an electrical appliance.

### BACKGROUND ART

A known connector suppresses water from entering into an inner containing space in which a ferrite core is contained and can suppress the water from attaching to a terminal by providing a seal member. A busbar is press-fitted and fixed to an inner housing, the ferrite core is formed with a pass-through hole for the busbar, and the busbar is made to pass through the pass-through hole. It is structured that the inner housing and the outer housing are assembled by containing a locking portion of the inner housing in a locking hole of the outer housing. Furthermore, it is structured that a seal member is arranged between the outer housing and the inner housing to be able to seal in an axial direction and a surface direction and thus water from the outside of a housing can be suppressed from entering. (Refer to Patent Document 1.)

### RELATED ART DOCUMENT

### Patent Document

Patent Document 1: JP-A-2020-113478

### SUMMARY OF THE INVENTION

### Problems to be Solved by the Invention

A wiring structure of an electrical appliance described in the above known Patent Document 1 is a structure which waterproofs between different constitutional 1 elements by sealing the connector in the axial direction and the surface direction; however, by sealing in the surface direction, a busbar supporting portion of the inner housing is exerted by reaction force caused by that the seal member is compressed in the surface direction and accordingly a problem exists in that positional accuracy of the busbar is not stabilized.

Furthermore, the busbar of the connector is conducted to a control board in the inside of the housing of the wiring structure of the electrical appliance by soldering. As shown by the seal structure of the known connector that is the wiring structure of the electrical appliance described in Patent Document 1, in the case where the connector is exerted by the reaction force caused by that the seal member is compressed in the surface direction, a problem exists in that when the busbar of the connector is made to pass through a through hole of the control board and is soldered, the connector is pushed back by reaction force of a area seal at an area seal portion between the housing and the connector, the amount of protrusion from the through hole of the control board of the busbar of the connector is not stabilized, and this affects solderability.

In the busbar extended in the direction where the reaction force of the area seal is generated, it needs to think of solving the problem of a deterioration in solderability by stabilizing the amount of protrusion of the busbar from the through hole of the control board.

The present application is to disclose a technique for solving the foregoing problem and an object of the present application is to provide a wiring structure of an electrical appliance which can stabilize the amount of protrusion of a busbar from a control board.

### Means for Solving the Problems

A wiring structure of an electrical appliance disclosed in the present application is a wiring structure of an electrical appliance, including: a connector which is fixed to a housing and has a connector housing made up of an outer connector housing and an inner connector housing; a busbar in which one side is arranged in the outer connector housing of the connector and the other side is extended to the outside of the inner connector housing of the connector; and a control board which is retained by the housing and through which the other side of the busbar passes. Then, the wiring structure of the electrical appliance includes a gasket which is attached by insertion between an outer peripheral portion of the connector and an inner peripheral portion of the housing which faces the outer peripheral portion of the connector, and seals a gap between the connector and the housing.

### Advantageous Effect of the Invention

According to the wiring structure of the electrical appliance disclosed in the present application, the gasket that seals the gap between the connector and the housing is attached by insertion between the outer peripheral portion of the connector and the inner peripheral portion of the housing which faces the outer peripheral portion of the connector, whereby the amount of protrusion of the busbar from the control board can be stabilized.

### BRIEF DESCRIPTION OF THE DRAWINGS

FIG. 1 is a perspective view showing a wiring structure of an electrical appliance according to Embodiment 1;

FIG. 2 is a perspective view showing a state seen from the back side of FIG. 1 in the wiring structure of the electrical appliance according to Embodiment 1;

FIG. 3 is a front view showing the wiring structure of the electrical appliance according to Embodiment 1;

FIG. 4 is a sectional view taken along the line A-A of FIG. 3 of the wiring structure of the electrical appliance according to Embodiment 1;

FIG. 5 is a front view showing a connector in the wiring structure of the electrical appliance according to Embodiment 1;

FIG. 6 is a sectional view corresponding to the line A-A of FIG. 3 of a wiring structure of an electrical appliance according to Embodiment 2;

FIG. 7 is an enlarged view of a part B of FIG. 6 of the wiring structure of the electrical appliance according to Embodiment 2;

FIG. 8 is a front view showing a wiring structure of an electrical appliance according to Embodiment 3;

FIG. 9 is a sectional view taken along the line C-C of FIG. 8 of the wiring structure of the electrical appliance according to Embodiment 3; and

FIG. 10 is an enlarged view of a part D of FIG. 9 of the wiring structure of the electrical appliance according to Embodiment 3.

### MODE FOR CARRYING OUT THE INVENTION

### Embodiment 1

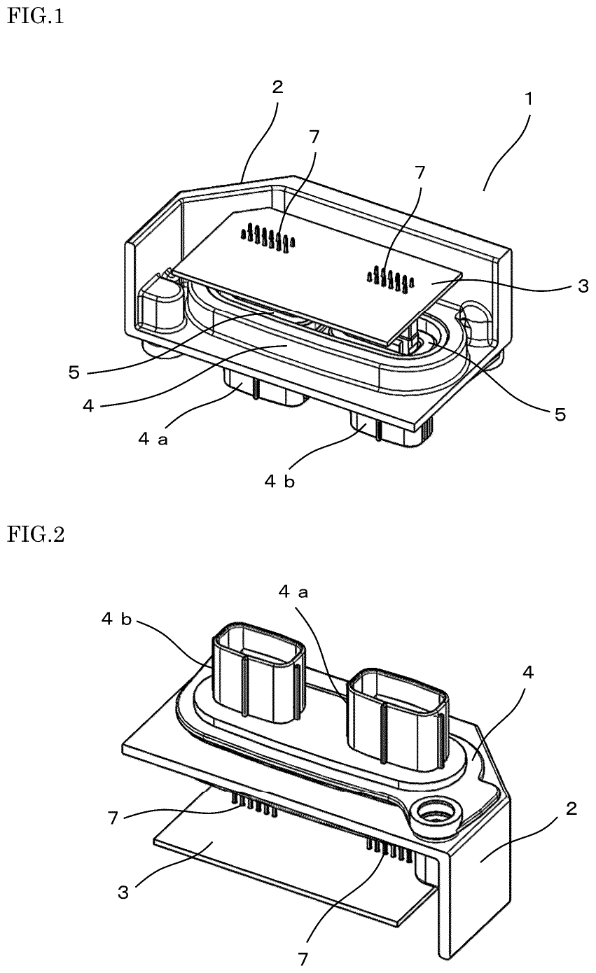

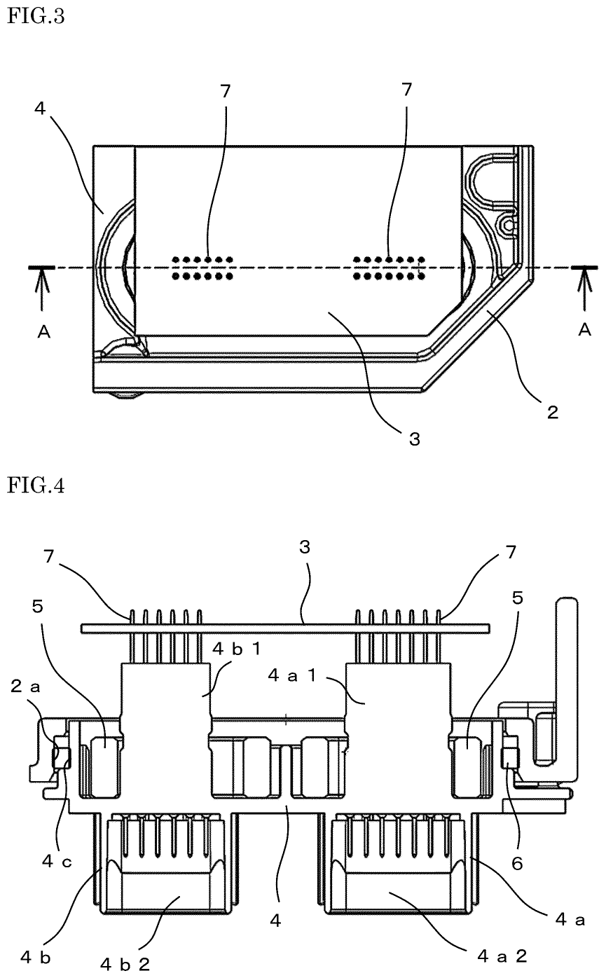

Hereinafter, Embodiment 1 of the present application will be described on the basis of FIG. 1 to FIG. 5; and, in each of the drawings, identical or equivalent members and parts will be described with the same reference numerals assigned thereto. FIG. 1 is a perspective view showing a wiring structure of an electrical appliance according to Embodiment 1. FIG. 2 is a perspective view showing a state seen from the back side of FIG. 1 in the wiring structure of the electrical appliance according to Embodiment 1. FIG. 3 is a front view showing the wiring structure of the electrical appliance according to Embodiment 1. FIG. 4 is a sectional view taken along the line A-A of FIG. 3 of the wiring structure of the electrical appliance according to Embodiment 1. FIG. 5 is a front view showing a connector in the wiring structure of the electrical appliance according to Embodiment 1.

The wiring structure of the electrical appliance of Embodiment 1 is a structural body which transmits and receives a signal to/from the outside and performs power control using the signal, and the wiring structure of the electrical appliance is characterized in that a housing and the connector are waterproofed by an axial seal. As an example of the wiring structure of the electrical appliance, there can be mentioned an appliance which needs a waterproof structure like a power conversion appliance and controls to a desired power by a control board in the inside of the structural body.

The known connector waterproofs the gap between the inner housing and the outer housing by the area seal and the axial seal. Because of being sealed by also the area seal, the reaction force of the seal member is generated in the direction where the busbar extends and the position of the busbar in the direction where the busbar extends is not stabilized.

The connector attached to the wiring structure of the electrical appliance of the present application is a structure in which a busbar is used to transmit and receive an electrical signal and the busbar is made to pass through a through hole formed in the control board in the inside of the housing and is soldered, thereby providing an electrical contact.

In the connector that transmits and receives the electrical signal, thin busbars are adjoined in short pitches and there is known that a soldering bridge is generated between the adjoined busbars depending on the length of the busbars protruded from the through holes of the control board.

In the case of the area seal structure like the background art, the connector is pushed back by the reaction force of the gasket, a tip end position of the busbar is easily deviated in the direction where the reaction force is generated and it is difficult to control the length of the busbar protruded from the through hole.

The structure of the present application is a structure in which an axial gasket is used to generate reaction force in a direction perpendicular to the direction where the busbar is protruded from the through hole and length protruded from the through hole of the busbar is stabilized to improve solderability.

A wiring structure of an electrical appliance 1 according to Embodiment 1 of the present application will be described on the basis of FIG. 1 through FIG. 4. A connector 4 is fixed to a housing 2 with screws and is composed of two connectors, a connector 4a and a connector 4b; the connector 4a is made up of an outer connector housing 4a2 and an inner connector housing 4a1. The connector 4b is made up of an outer connector housing 4b2 and an inner connector housing 4b1.

One side of a plurality of busbars 7 is arranged in the outer connector housing 4a2 and the inner connector housing 4a1 of the connector 4; and the other side is extended to the outside of the inner connector housing 4al of the connector 4a. Furthermore, one side of a plurality of busbars 7 is arranged in the outer connector housing 4b2 and the inner connector housing 4b1 of the connector 4b; and the other side is extended to the outside of the inner connector housing 4b1 of the connector 4b.

A control board 3 is retained by the housing 2; and the other sides of the busbars 7, 7 are respectively extended from the inner connector housing 4a1 of the connector 4a and from the inner connector housings 4b1 of the connector 4b and pass through the through holes of the control board 3.

The connector 4 for signaling is susceptible to noise and thus a ferrite core 5 is often attached. A gasket 6 is attached by insertion between an outer peripheral portion 4c of the connector 4 and an inner peripheral portion 2a of the housing 2 which faces the outer peripheral portion 4c of the connector 4 to seal a gap between the connector 4 and the housing 2. The gasket 6 is positioned in a range of the axial length of the ferrite core 5 and thus the length of the busbar 7 can be minimized.

The connector 4 is fixed to the housing 2 with the screws in a state where the gasket 6 is assembled to the connector 4. Then, after the connector 4 is fixed to the housing 2, the control board 3 is fixed to the housing 2 with screws, the busbars 7 are made to pass through the through holes of the control board 3, and the control board 3 and the busbars 7 are electrically conducted by soldering.

When the connector 4 is attached to the housing 2, reaction force is difficult to generate in a reverse direction to a direction in which the connector 4 is pressed to the housing 2 and reaction force of the gasket 6 is generated in a direction perpendicular to an attaching direction of the connector 4; therefore, positional accuracy of a tip end the busbar 7 that is soldered to the control board stabilized and thus solderability becomes good and the accuracy of the amount of protrusion of the busbar 7 from the control board 3 becomes good.

The gasket 6 shown in FIG. 4 is an axial seal structure; however, it is no problem that the gasket 6 of the structure that makes the busbar 7 the shortest is even an area seal structure. The volume of conductive material is reduced by shortening the length of the busbar 7 and thus there is a merit that material costs are inexpensive and electrical resistance is reduced.

Furthermore, the plurality of busbars 7 arranged in the connector 4 makes a circuit in which current goes and returns by generally adjacent busbars 7; and inductance is proportional to the length of the busbar 7. Therefore, if the length of the busbar 7 is shortened like the present application, the inductance is reduced; and when noise is superimposed on the busbar 7, voltage fluctuation is reduced; thus, an error is reduced with respect to a desired voltage.

Next, the structure of the connector 4 shown in FIG. 5 will be described. There are many cases where the wiring structure of the electrical appliance 1 uses a plurality of connectors 4, and FIG. 5 is a structure in which two connectors 4a, 4b that are essentially separated components are molded side by side. By molding side by side, the connector 4 is increased in size and an axial seal attachment portion is apt to fall down due to the contraction of resin during molding. Thus, a reinforcement rib 8 is provided at a central portion of the connector 4 to take a countermeasure against falling down of a resin wall for attaching the gasket 6.

As shown in FIG. 5, when the ferrite core 5 is attached in the inside of the connector 4, the inner peripheral length of the gasket 6 is elongated and moreover deformation becomes prominent; thus, the countermeasure by the reinforcement rib 8 is effectively acted. Furthermore, the ferrite core 5 of FIG. 5 is not a circle, but a straight portion 5a is provided. In FIG. 5, the ferrite core 5 is outserted, a positioning structure 4d is attached to the connector 4, and the straight portion 5a of the ferrite core 5 is used and positioning can be performed.

Additionally, it becomes possible to fix the ferrite core 5 during molding by applying injection pressure of during resin molding to the ferrite core 5 and by pressing a metal mold to the straight portion 5a of the ferrite core 5; thus, insert molding can be performed. Further, when two or more ferrite cores 5 are attached to the connector 4, there is a merit that the cost of the metal mold of the ferrite core 5 can be reduced by forming the ferrite core 5 into the same shape.

Besides, a connector frontage to be connected to the outside and the busbars to be soldered are extended straightly; however, there is also easily considered a connector structure in which busbars are bent and a direction of the busbars to be soldered is different from a direction of the connector frontage.

### Embodiment 2

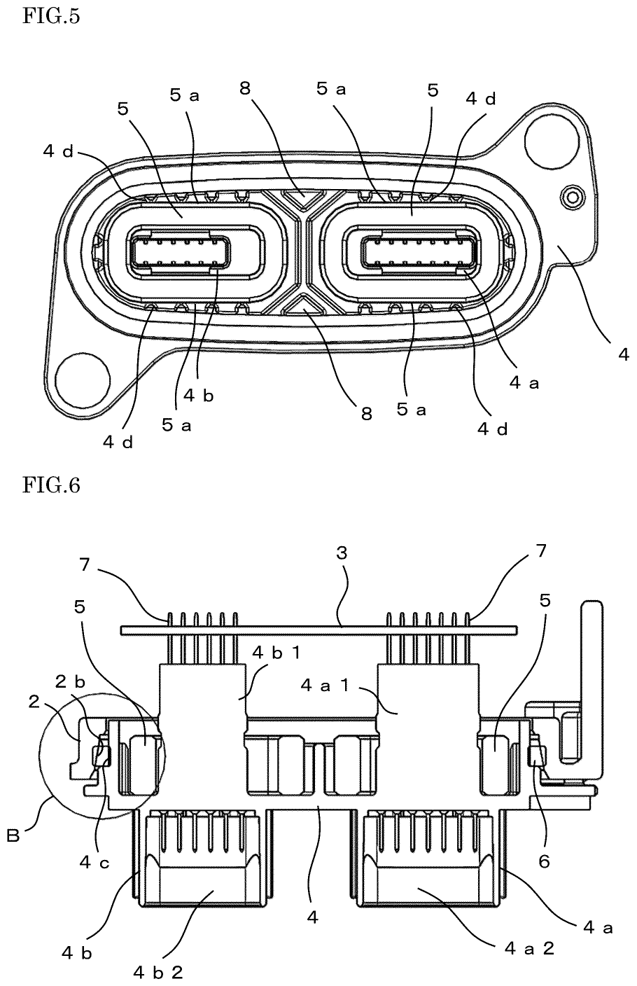

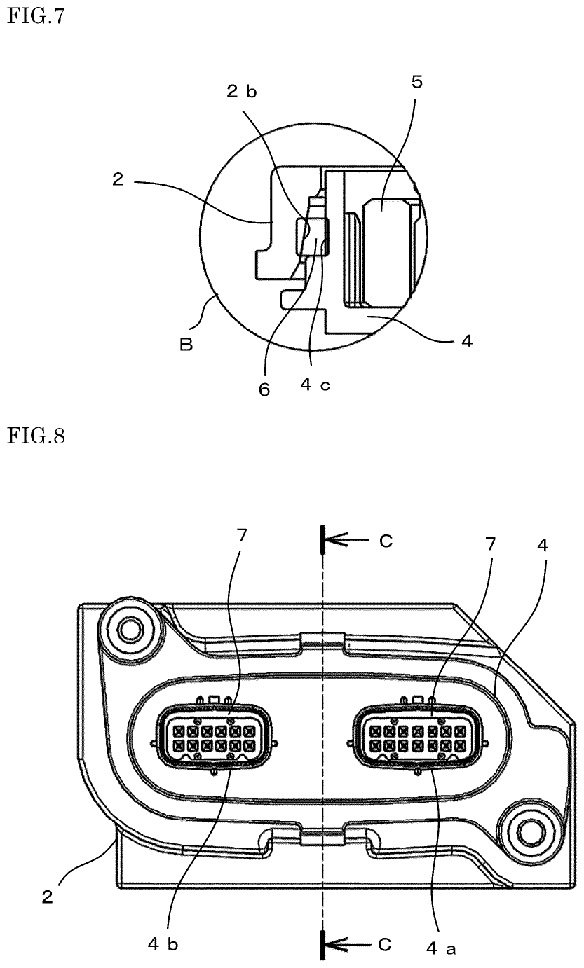

Next, Embodiment 2 will be described on the basis of FIG. 6 and FIG. 7; and, in each of the drawings, identical or equivalent members and parts will be described with the same reference numerals assigned thereto. FIG. 6 is a sectional view corresponding to the line A-A of FIG. 3 of a wiring structure of an electrical appliance according to Embodiment 2. FIG. 7 is an enlarged view of a part B of FIG. 6 of the wiring structure of the electrical appliance according to Embodiment 2.

As shown in FIG. 7, an inner peripheral portion 2b of a housing 2 is formed in a tapered shape. The inner peripheral portion 2b of the housing 2 is formed in the tapered shape; thus, it becomes easy to attach a connector 4 attached with a gasket 6 to the inner peripheral portion 2b of the housing 2 and it reduces the risk of breakage of the gasket 6 due to sandwiching the gasket 6 between the inner peripheral portion 2b of the housing 2 and an outer peripheral portion 4c of the connector 4.

### Embodiment 3

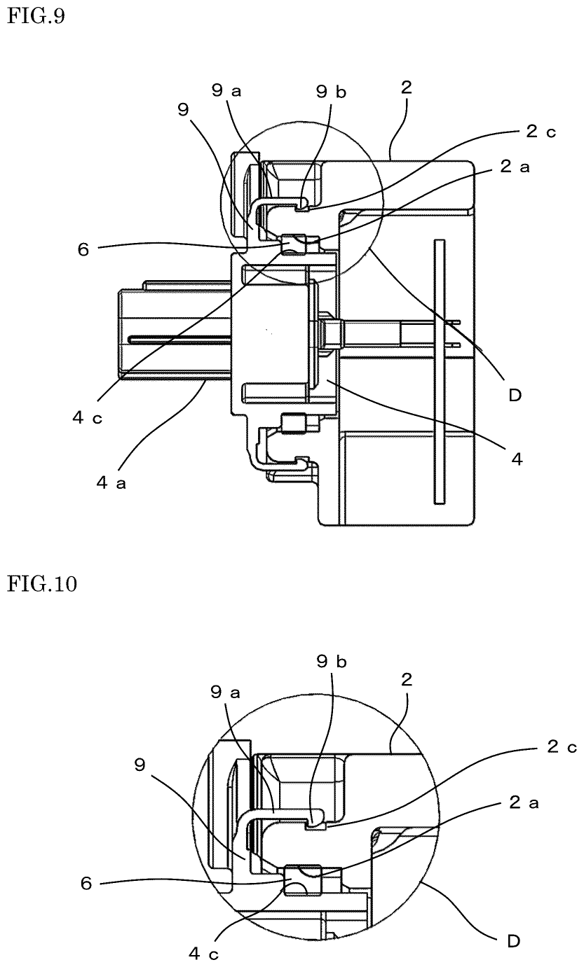

Next, Embodiment 3 will be described on the basis of FIG. 8 through FIG. 8; and, in each of the drawings, identical or equivalent members and parts will be described with the same reference numerals assigned thereto. FIG. 8 is a front view showing a wiring structure of an electrical appliance according to Embodiment 3. FIG. 9 is a sectional view taken along the line C-C of FIG. 8 of the wiring structure of the electrical appliance according to Embodiment 3. FIG. 10 is an enlarged view of a part D of FIG. 9 of the wiring structure of the electrical appliance according to Embodiment 3.

In Embodiment 3, an elastic engagement body 9 is provided on a connector 4; the elastic engagement body 9 has an arm portion 9a that extends to an outer peripheral portion side of a housing 2; a tip end portion of the arm portion 9a is provided with an engagement piece 9b formed in, for example, a claw-shape; and an outer peripheral portion of the housing 2 is provided with an engagement portion 2c that is formed in, for example, a concave portion with which the engagement piece 9b of the elastic engagement body 9 engages. It is a structure in which in the case of attaching the connector 4 to the housing 2, in a state where the arm portion 9a of the elastic engagement body 9 is deflected, when the connector 4 slips on the outer peripheral portion of the housing 2 and comes near to the engagement portion 2c formed by the concave portion of the housing 2, the engagement piece 9b of the elastic engagement body 9 engages with the engagement portion 2c formed by the concave portion of the housing 2 and the connector 4 is fixed to the housing 2.

In the structure of FIG. 9 and FIG. 10, the description has been made on the case where the engagement portion 2c of the housing 2 is the concave portion; however, the engagement portion 2c of the housing 2 is formed in a convex portion and an engagement hole is provided in a tip end portion of the engagement piece 9b of the elastic engagement body 9 provided on the connector 4, whereby the same effect can be exhibited even when the engagement piece 9b formed by the engagement hole of the elastic engagement body 9 is made to engage with the convex portion of the engagement portion 2c of the housing 2. Furthermore, if one or more elastic engagement bodies 9 are provided, force for fixing to the housing 2 can be demonstrated; thus, the number of the elastic engagement bodies 9 is not limited.

Further, the amount of crush of the gasket 6 is partially increased in a portion other than a waterproof portion of the gasket 6, thereby also enabling the connector 4 to fix to the housing 2. Of course, a gap is provided between the connector 4 and the housing 2 and an elastic body different from the gasket 6 is used to stuff the elastic body into the gap, thereby also enabling the connector 4 to fix to the housing 2.

The present application describes various exemplified embodiments and examples; however, various features, aspects, and functions described in one or a plurality of embodiments are not limited to specific embodiments, but are applicable to embodiments individually or in various combinations thereof. Therefore, countless modified examples not exemplified are assumed in technical ranges disclosed in the description of the present application. For example, there include: a case in which at least one constitutional element is modified; a case, added; or a case, omitted; and a case in which at least one constitutional element is extracted to combine with constitutional elements of other embodiments.

### INDUSTRIAL APPLICABILITY

The present application is suitable for actualizing a wiring structure of an electrical appliance which can stabilize the amount of protrusion of a busbar from a control board.

### DESCRIPTION OF REFERENCE NUMERALS

1 Wiring structure of electrical appliance, 2 Housing, 2a, 2b Inner peripheral portion, 3 Control board, 4, 4a, 4b Connector, 4a1, 4b1 Inner connector housing, 4a2, 4b2 Outer connector housing, 4c Outer peripheral portion, 4d Positioning structure, 5 Ferrite core, 5a Straight portion, 6 Gasket, 7 Busbar, 8 Reinforcement rib, 9 Elastic engagement body, 9a Arm portion, 9b Engagement piece

1. A wiring structure of an electrical appliance, comprising:
a connector which is fixed to a housing and has a connector housing made up of an outer connector housing and an inner connector housing;
a busbar in which one side is arranged in the outer connector housing of the connector and the other side is extended to the outside of the inner connector housing of the connector; and
a control board which is retained by the housing and through which the other side of the busbar passes,
wherein the wiring structure of the electrical appliance includes a gasket which is attached by insertion between an outer peripheral portion of the connector and an inner peripheral portion of the housing which faces the outer peripheral portion of the connector, and seals a gap between the connector and the housing.

2. The wiring structure of the electrical appliance according to claim 1,
wherein the busbar is surrounded by a ferrite core; and
the gasket is arranged in a range of the axial length of the ferrite core.

3. The wiring structure of the electrical appliance according to claim 1, wherein a contact surface with the gasket of the housing is formed in a tapered shape.

4. The wiring structure of the electrical appliance according to claim 1,
wherein an elastic engagement body is provided on the connector, and an engagement portion in which an engagement piece of the elastic engagement body engages with an outer peripheral portion of the housing is provided.

5. The wiring structure of the electrical appliance according to claim 2,
wherein the ferrite core has a straight portion.

6. The wiring structure of the electrical appliance according to claim 2,
wherein the ferrite core is provided in plural numbers, and a reinforcement rib is provided between the ferrite cores.

7. The wiring structure of the electrical appliance according to claim 6,
wherein the plurality of ferrite cores is made up of the same shaped ferrite cores.

8. The wiring structure of the electrical appliance according to claim 2,
wherein a contact surface with the gasket of the housing is formed in a tapered shape.

9. The wiring structure of the electrical appliance according to claim 2,
wherein an elastic engagement body is provided on the connector, and an engagement portion in which an engagement piece of the elastic engagement body engages with an outer peripheral portion of the housing is provided.

10. The wiring structure of the electrical appliance according to claim 5,
wherein the ferrite core is provided in plural numbers, and a reinforcement rib is provided between the ferrite cores.

11. The wiring structure of the electrical appliance according to claim 10,
wherein the plurality of ferrite cores is made up of the same shaped ferrite cores.
